(19) United States
(12) Patent Application Publication
(10) Pub. No.: US 2019/0341358 A1
(43) Pub. Date: Nov. 7, 2019

(54) METHOD OF FORMING SEMICONDUCTOR DEVICE USING POLISHING RESISTANCE PATTERN

(71) Applicant: SAMSUNG ELECTRONICS CO., LTD., SUWON-SI (KR)

(72) Inventors: YANG HEE LEE, Hwaseong-si (KR); Jong Hyuk Park, Hwaseong-si (KR); Jin Woo Bae, Hwaseong-si (KR); Choong Seob Shin, Hwaseong-si (KR); Hyo Jin Oh, Hwaseong-si (KR); Bo Un Yoon, Hwaseong-si (KR); Il Young Yoon, Hwaseong-si (KR); Hee Sook Cheon, Hwaseong-si (KR)

(21) Appl. No.: 16/252,810

(22) Filed: Jan. 21, 2019

(30) Foreign Application Priority Data
May 3, 2018 (KR) 10-2018-0051004

(51) Int. Cl. H01L 23/00; H01L 21/3105; H01L 21/02

(52) U.S. Cl. CPC H01L 23/562; H01L 21/31053; H01L 21/02345; H01L 21/02164; H01L 21/02321

(57) ABSTRACT

A method of forming a semiconductor device, includes: forming a design pattern on a substrate, wherein the design pattern protrudes from the substrate; forming a filling layer on the substrate, wherein the filling layer at least partially covers the design pattern; forming a polishing resistance pattern adjacent to the design pattern in the filling layer using a laser irradiation process and/or an ion implantation process; and removing the filling layer using a chemical mechanical polishing (CMP) process to expose the design pattern.

### CROSS-REFERENCE TO RELATED APPLICATION

This U.S. non-provisional patent application claims priority under 35 U.S.C. § 119 to Korean Patent Application No. 10-2018-0051004, filed on May 3, 2018, in the Korean Intellectual Property Office (KIPO), the disclosure of which is incorporated by reference herein in its entirety.

### TECHNICAL FIELD

Exemplary embodiments of the present inventive concept relate to a method of forming a semiconductor device, and more particularly, to a method of forming a semiconductor device using a polishing resistance pattern.

### DISCUSSION OF THE RELATED ART

Generally, a planarization technique using a chemical mechanical polishing (CMP) process has been applied to the formation of semiconductor devices. A material removal rate in a CMP process varies depending on constituent materials of an exposed surface and varying heights of the exposed surface. In the CMP process, a pattern having a surface with large differences in height tends to be vulnerable to having an edge of the pattern collapse.

### SUMMARY

According to an exemplary embodiment of the present inventive concept, a method of forming a semiconductor device, includes: forming a design pattern on a substrate, wherein the design pattern protrudes from the substrate; forming a filling layer on the substrate, wherein the filling layer at least partially covers the design pattern; forming a polishing resistance pattern adjacent to the design pattern in the filling layer using a laser irradiation process and/or an ion implantation process; and removing the filling layer using a chemical mechanical polishing (CMP) process to expose the design pattern.

According to an exemplary embodiment of the present inventive concept, a method of forming a semiconductor device, includes: forming a design pattern on a substrate, the substrate including a trench; forming a polishing resistance pattern in the design pattern using a laser irradiation process and/or an ion implantation process; forming a filling layer on the design pattern, wherein the filling layer fills the trench and covers the design pattern and the polishing resistance pattern; and removing the filling layer using a chemical mechanical polishing (CMP) process to expose the polishing resistance pattern.

According to an exemplary embodiment of the present inventive concept, a method of forming a semiconductor device, includes: forming a protruding design pattern on a substrate; forming a filling layer on the substrate, wherein the filling layer covers side surfaces and an upper surface of the design pattern; forming a polishing resistance pattern adjacent to the design pattern and in the filling layer using a laser irradiation process; and planarizing the filling layer and the polishing resistance pattern using a chemical mechanical polishing (CMP) process until the design pattern is exposed. The polishing resistance pattern is disposed between an edge of the substrate and the design pattern, and in the CMP process, a material removal rate of the polishing resistance pattern is different from that of the filling layer.

According to an exemplary embodiment of the present inventive concept, a method of forming a semiconductor device, includes: forming a design pattern on a substrate; forming a filling layer on the design pattern; forming a polishing resistance pattern in the filling layer and between an edge of the substrate and the design pattern, wherein the filling layer is disposed between the design pattern and the polishing resistance pattern; and removing the filling layer to expose the design pattern.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawing, wherein:

FIG. 1 is a diagram illustrating a method of forming a semiconductor device according to an exemplary embodiment of the present inventive concept;

FIGS. 2, 3, 4, 5, 6, 7, 8, 9, 10 and 11 are cross-sectional views illustrating methods of forming a semiconductor device taken along line I-I′ of FIG. 1, according to an exemplary embodiment of the present inventive concept;

FIG. 12 is an enlarged view showing a portion of FIG. 1 according to an exemplary embodiment of the present inventive concept;

FIGS. 13, 14, 15, 16, 17, 18, 19 and 20 are cross-sectional views illustrating methods of forming a semiconductor device taken along line II-II′ of FIG. 12, according to an exemplary embodiment of the present inventive concept; and

FIGS. 21, 22, 23 and 24 are cross-sectional views illustrating methods of forming a semiconductor device according to an exemplary embodiment of the present inventive concept.

### DETAILED DESCRIPTION OF THE EMBODIMENTS

Exemplary embodiments of the present inventive concept will be described more fully hereinafter with reference to the accompanying drawings.

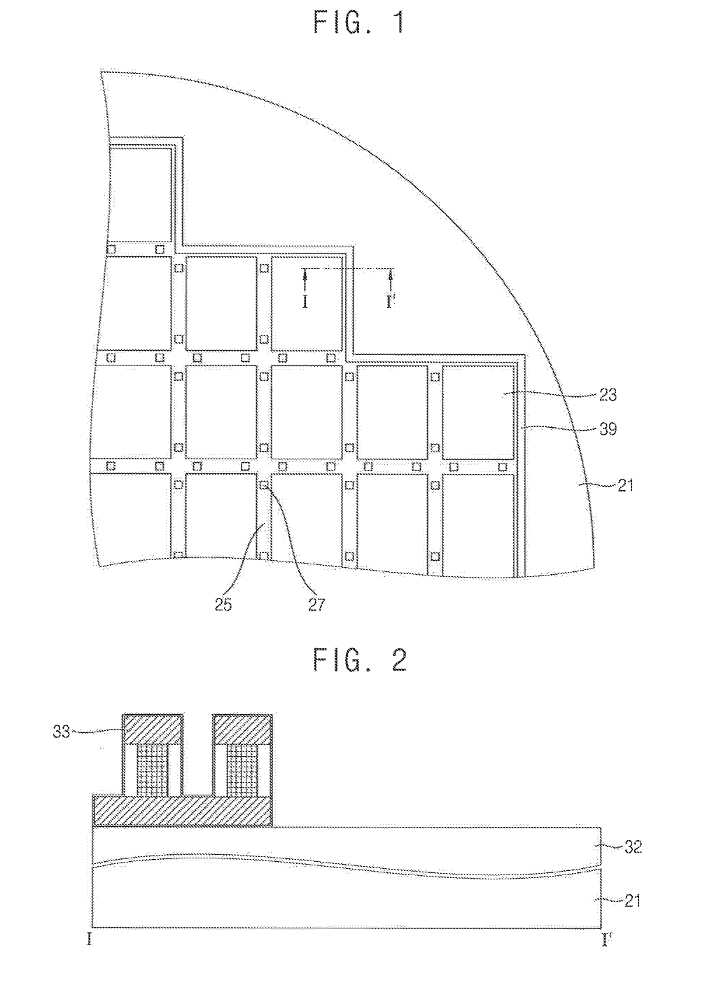

FIG. 1 is a diagram illustrating a method of forming a semiconductor device according to an exemplary embodiment of the present inventive concept, and FIGS. 2, 3, 4 and 5 are cross-sectional views illustrating a method of forming a semiconductor device taken along line I-I′ of FIG. 1 according to an exemplary embodiment of the present inventive concept.

Referring to FIG. 1, the method of forming the semiconductor device, according to an exemplary embodiment of the present inventive concept, includes forming a plurality of chips 23 on a substrate 21. The plurality of chips 23 may be arranged on the substrate 21 in a row direction and a column direction. A scribe lane 25 may be formed between each of the plurality of chips 23. For example, a scribe lane 25 may be formed between adjacent chips of the plurality of chips 23. A plurality of trench keys 27 may be formed in each scribe lane 25. A polishing resistance pattern 39 may be formed on the substrate 21. The polishing resistance pattern 39 may be formed between an edge of the substrate 21 and the plurality of chips 23. The polishing resistance pattern 39 may at least partially surround outer sides of the plurality of chips 23. The polishing resistance pattern 39 may be closer to the edge of the substrate 21 than the plurality of chips 23.

Referring to FIGS. 1 and 2, a lower layer 32 may be formed on the substrate 21. A design pattern 33 may be formed on the lower layer 32.

The substrate 21 may be a semiconductor substrate such as a silicon wafer or a silicon-on-insulator (SOI) wafer. The substrate 21 may include, for example, glass, sapphire, a metal, Teflon, a printed circuit board (PCB), a flat panel, or combinations thereof. In an exemplary embodiment of the present inventive concept, the substrate 21 may be a silicon wafer having a diameter of about 300 mm. The lower layer 32 may include various types of thin films formed of a conductive material and/or an insulating material. The lower layer 32 may be formed in the substrate 21 and/or on the substrate 21. The lower layer 32 may entirely cover one surface of the substrate 21. For example, the lower layer 32 may cover an upper surface of the substrate 21. An upper surface of the lower layer 32 may include an uneven portion. However, hereinafter in the present disclosure, it will be assumed that the upper surface of the lower layer 32 is flat.

The design pattern 33 may include a plurality of conductive patterns, a plurality of insulating patterns, or combinations thereof. For example, the design pattern 33 may include cell capacitors of a dynamic random access memory (DRAM), cell mats of a VNAND memory, pixel regions of a complementary metal-oxide-semiconductor (CMOS) image sensor, or various interconnection structures. The design pattern 33 may be formed to protrude in a vertical direction with respect to an upper surface of the lower layer 32. The design pattern 33 may include a plurality of protruding regions and recessed regions formed between the plurality of protruding regions. For example, the design pattern 33 may include a trench. The design pattern 33 may be formed in the plurality of chips 23. The upper surface of the lower layer 32 may be exposed between the edge of the substrate 21 and the design pattern 33. For example, the design pattern 33 might not entirely cover the upper surface of the lower layer 32. For example, only a portion of the upper surface of the lower layer 32 might be exposed. The exposed portion of the upper surface of the lower layer 32 may be lower than an upper end of the design pattern 33. For example, there may be a relatively large difference in height between the upper end of the design pattern 33 and the exposed portion of the upper surface of the lower layer 32.

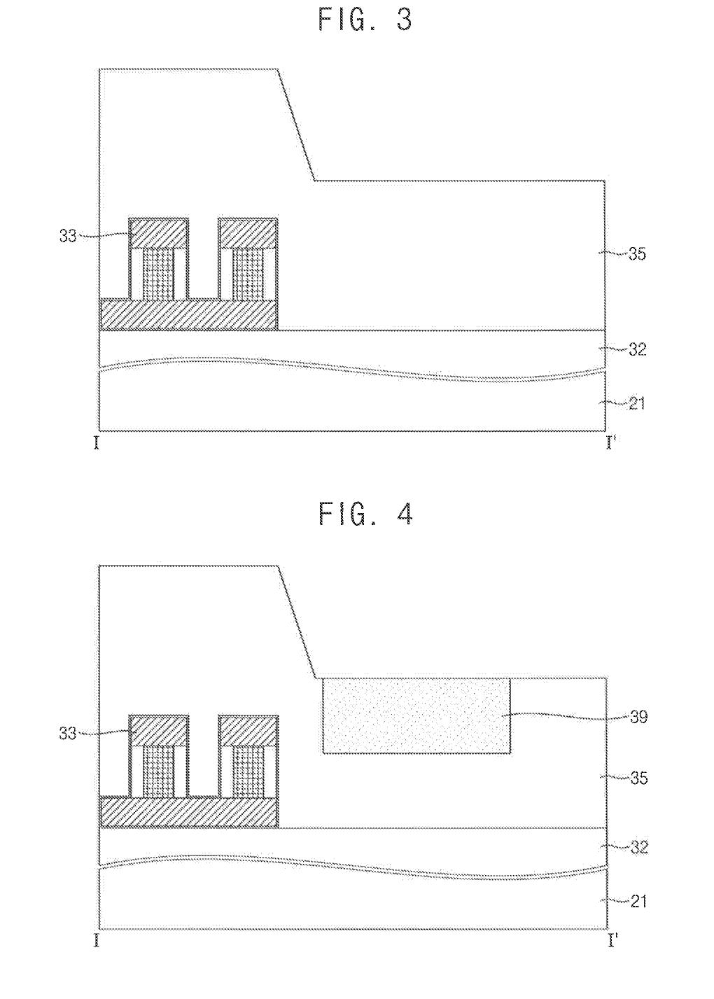

Referring to FIGS. 1 and 3, a filling layer 35 may be formed on the lower layer 32 and may cover the design pattern 33. The filling layer 35 may fill the recessed regions of the design pattern 33 and cover the protruding regions of the design pattern 33. The filling layer 35 may cover the lower layer 32 between the edge of the substrate 21 and the design pattern 33. The filling layer 35 may cover side surfaces of the design pattern 33. An upper surface of the filling layer 35 may be formed with a height greater than that of an uppermost end of the design pattern 33.

The filling layer 35 may include a material different from that of the design pattern 33. A material removal rate in a chemical mechanical polishing (CMP) process may be determined depending on chemical reactivity and a physical binding force of materials constituting an exposed surface. A material removal rate of the filling layer 35 may be different from that of the design pattern 33. In an exemplary embodiment of the present inventive concept, the material removal rate of the filling layer 35 may be higher than that of the upper end of the design pattern 33. The filling layer 35 may include, for example, an oxide such as silicon oxide, a nitride such as silicon nitride, a semiconductor such as polysilicon, or a combination thereof. In an exemplary embodiment of the present inventive concept, the filling layer 35 may include silicon oxide.

Referring to FIGS. 1 and 4, the polishing resistance pattern 39 may be formed adjacent to the design pattern 33 and in the filling layer 35. The forming of the polishing resistance pattern 39 may include a laser irradiation process, an ion implantation process, or a combination thereof.

In an exemplary embodiment of the present inventive concept, the forming of the polishing resistance pattern 39 may include a process of locally irradiating a predetermined region of the filling layer 35 with a laser. In an exemplary embodiment of the present inventive concept, the forming of the polishing resistance pattern 39 may include a process of locally implanting ions into the predetermined region of the filling layer 35. For example, the forming of the polishing resistance pattern 39 may include a process of locally implanting carbon (C), nitrogen (N), or a combination thereof into the predetermined region of the filling layer 35. In an exemplary embodiment of the present inventive concept, the forming of the polishing resistance pattern 39 may include a process of locally implanting ions into the predetermined region of the filling layer 35 and a process of heat treatment.

The polishing resistance pattern 39 may be formed between the edge of the substrate 21 and the design pattern 33. The polishing resistance pattern 39 may be closer to the edge of the substrate 21 than the design pattern 33. The filling layer 35 may be between the polishing resistance pattern 39 and the design pattern 33 and between the polishing resistance pattern 39 and the lower layer 32. A lowermost end of the polishing resistance pattern 39 may be formed lower than the uppermost end of the design pattern 33. An uppermost end of the polishing resistance pattern 39 may be formed higher than the uppermost end of the design pattern 33.

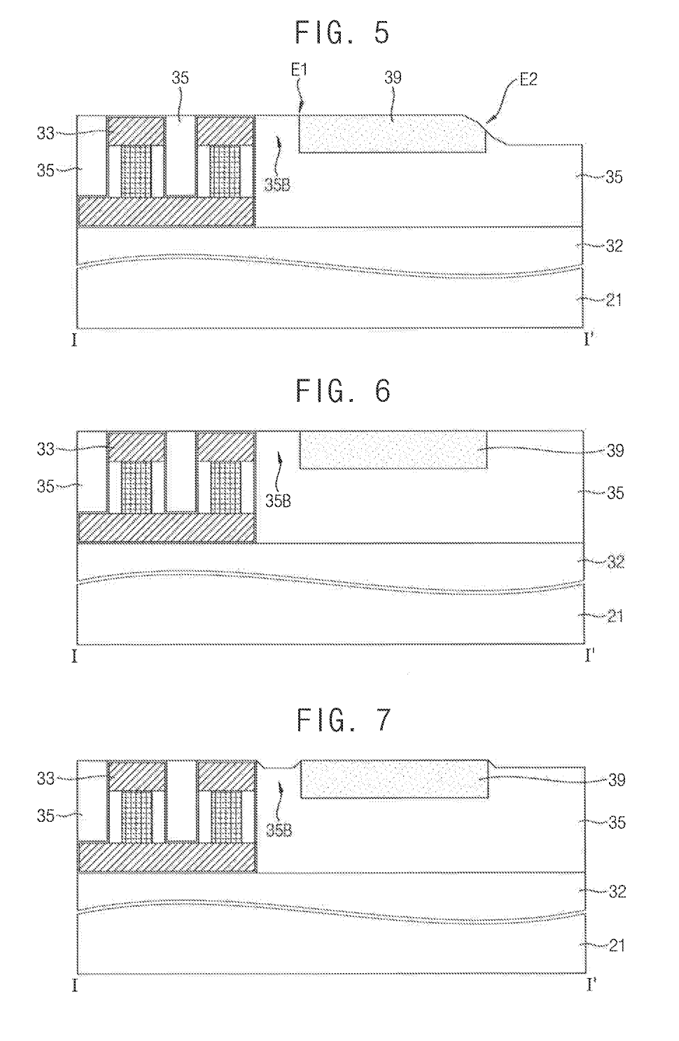

Referring to FIGS. 1 and 5, the filling layer 35 may be partially removed using a CMP process so that the design pattern 33 may be exposed. For example, an upper surface of the design pattern 33 may be exposed. In the CMP process, a material removal rate of the polishing resistance pattern 39 may be different from that of the filling layer 35. The material removal rate of the polishing resistance pattern 39 may be lower than that of the filling layer 35. In an exemplary embodiment of the present inventive concept, the material removal rate of the polishing resistance pattern 39 may be lower than that of the filling layer 35 and higher than that of the design pattern 33. In an exemplary embodiment of the present inventive concept, the material removal rate of the polishing resistance pattern 39 may be substantially identical to that of the design pattern 33.

When the filling layer 35 is partially removed, so that the design pattern 33 is exposed, the polishing resistance pattern 39 may be partially removed so that a thickness of the polishing resistance pattern 39 may be reduced. An inter-pattern region 35B of the filling layer 35 may remain between the design pattern 33 and the polishing resistance pattern 39. Upper surfaces of the design pattern 33, the inter-pattern region 35B of the filling layer 35, and the polishing resistance pattern 39 may be exposed on substantially the same plane. When the filling layer 35 is partially removed so that the design pattern 33 is exposed, the polishing resistance pattern 39 may prevent one or more edges of the design pattern 33 from collapsing, which is referred to herein as “edge collapse”. For example, an edge collapse may be formed from the erosion or degradation of an edge.

In an exemplary embodiment of the present inventive concept, the polishing resistance pattern 39 may include a first edge E1 and a second edge E2 opposite the first edge E1. The first edge E1 may be disposed between the design pattern 33 and the second edge E2 is. The second edge E2 may be closer to the edge of the substrate 21 than the first edge E1. The second edge E2 may have a larger edge collapse than the first edge E1. For example, the second edge E2 may be slanted with respect to an upper surface of the polishing resistance pattern 39. For example, the polishing resistance pattern 39 may have a rectangular shape before the removal of the filling layer 35. Further, during the removal of the filling layer 35, the second edge E2 may erode and become a collapsed edge. In addition, the more that an edge is eroded, the more collapsed the edge will be.

In an exemplary embodiment of the present inventive concept, the partial removal of the filling layer 35 may include planarizing the filling layer 35 and the polishing resistance pattern 39 until the design pattern 33 is exposed. A CMP process may be used for the planarizing of the filling layer 35 and the polishing resistance pattern 39.

FIGS. 6 to 9 are cross-sectional views illustrating methods of forming a semiconductor device taken along line I-I′ of FIG. 1 according to an exemplary embodiment of the present inventive concept.

Referring to FIGS. 1 and 6, the filling layer 35 and the polishing resistance pattern 39 may be planarized using a CMP process so that the design pattern 33 may be exposed. Upper surfaces of the design pattern 33, the filling layer 35, and the polishing resistance pattern 39 may be exposed on substantially the same plane.

Referring to FIGS. 1 and 7, the filling layer 35 and the polishing resistance pattern 39 may be planarized using a CMP process until the design pattern 33 is exposed. An inter-pattern region 35B of the filling layer 35 may be provided between the design pattern 33 and the polishing resistance pattern 39. An upper surface of the inter-pattern region 35B may be formed to be lower than upper surfaces of the design pattern 33 and the polishing resistance pattern 39. For example, the inter-pattern region 35B may have a concave shape or may be indented. In addition, the portion of the filling layer 35 between the edge of the substrate 21 and the polishing resistance pattern 39 may be lower than upper surfaces of the design pattern 33 and the polishing resistance pattern 39.

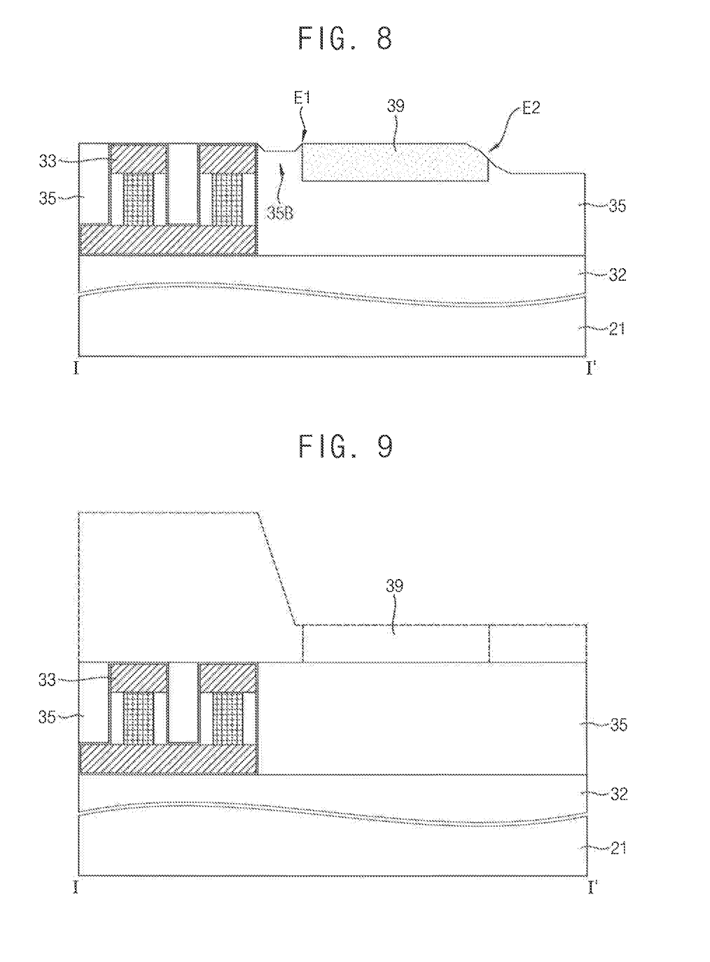

Referring to FIGS. 1 and 8, the filling layer 35 and the polishing resistance pattern 39 may be planarized using a CMP process so that the design pattern 33 may be exposed. An upper surface of an inter-pattern region 35B may be formed lower than upper surfaces of the design pattern 33 and the polishing resistance pattern 39. For example, the upper surfaces of the design pattern 33 and the polishing resistance pattern 39 may be positioned at a greater height than that of the upper surface of the inter-pattern region 35B. A second edge E2 may have a larger edge collapse than a first edge E1. For example, the first edge E1 might not have an edge collapse. The second edge E2 may be relatively close to the edge of the substrate 21. For example, the second edge E2 may be closer to the edge of the substrate 21 when compared to the first edge E1.

Referring to FIGS. 1 and 9, according to an exemplary embodiment of the present inventive concept, while the filling layer 35 is partially removed so that the design pattern 33 is exposed, the polishing resistance pattern 39 may be fully removed. Upper surfaces of the design pattern 33 and the filling layer 35 may be exposed on substantially the same plane.

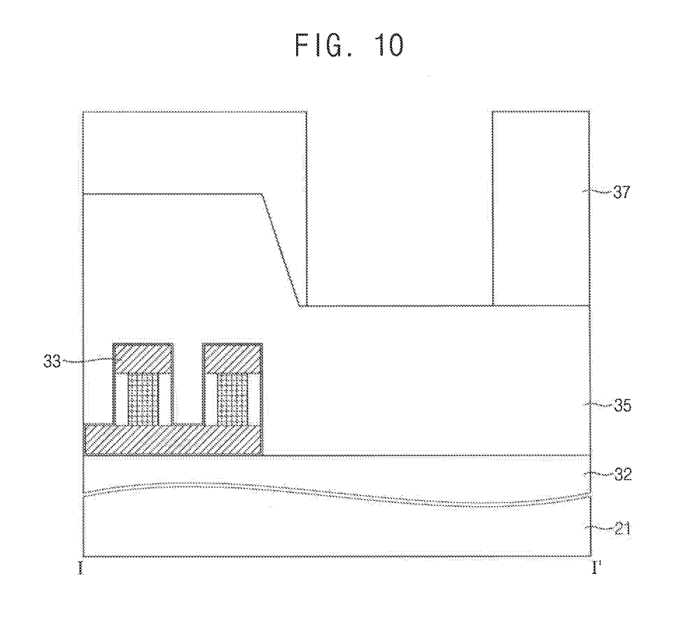

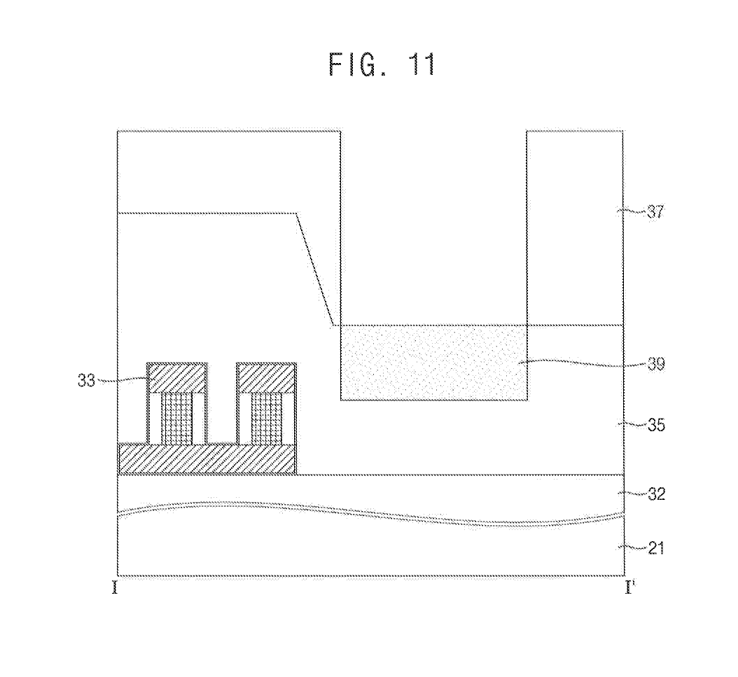

FIGS. 10 and 11 are cross-sectional views illustrating a method of forming a semiconductor device taken along line I-I′ of FIG. 1 according to an exemplary embodiment of the present inventive concept.

Referring to FIGS. 1 and 10, a mask layer 37 may be formed on the filling layer 35. The mask layer 37 may cover the design pattern 33 and partially expose the filling layer 35 at an outer side of the design pattern 33. For example, the exposed portion of the filling layer 35 does not overlap the design pattern 33. The mask layer 37 may include, for example, a hard mask pattern, a photoresist pattern, or a combination thereof.

Referring to FIGS. 1 and 11, a polishing resistance pattern 39 may be formed in the exposed portion of the filling layer 35 using, for example, a laser irradiation process, an ion implantation process, or a combination thereof. A mask layer 37 may protect a design pattern 33 while the laser irradiation process, the ion implantation process, or a combination thereof is performed. After the polishing resistance pattern 39 is formed, the mask layer 37 may be removed.

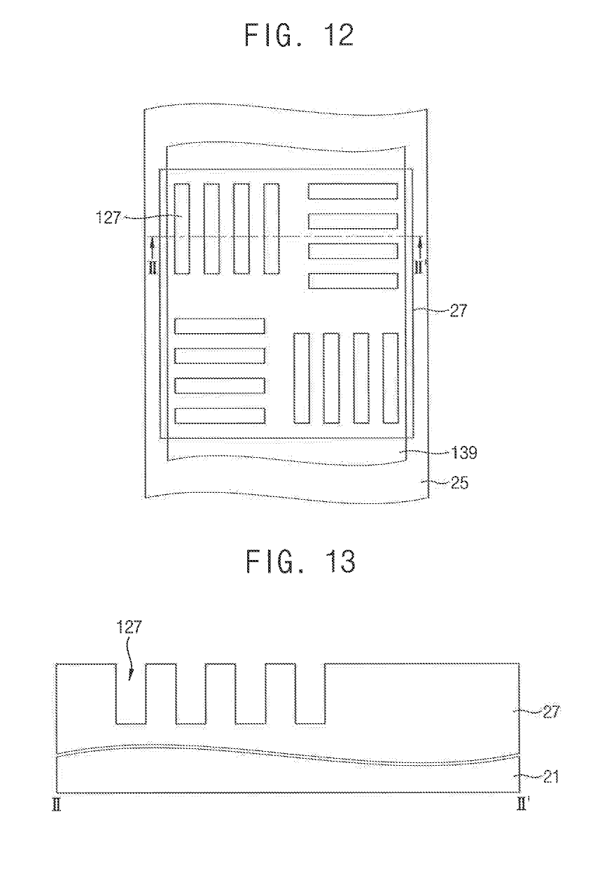

FIG. 12 is an enlarged view showing a portion of FIG. 1 according to an exemplary embodiment of the present inventive concept, and FIGS. 13, 14, 15, 16, 17, 18, 19 and 16 are cross-sectional views of a method of forming a semiconductor device taken along line II-II′ of FIG. 12 according to an exemplary embodiment of the present inventive concept.

Referring to FIGS. 12 and 13, the trench key 27 may be formed in the scribe lane 25 on the substrate 21. The trench key 27 may include the plurality of trenches 127. In an exemplary embodiment of the present inventive concept, the trench key 27 may include a nitride such as silicon nitride, a semiconductor such as polysilicon, or a combination thereof. The trench key 27 may correspond to a design pattern. The trench key 27 may include a structure in which a plurality of thin films are alternately stacked.

Referring to FIGS. 12 and 14, polishing resistance patterns 139 and 139B may be formed in the trench key 27 using, for example, a laser irradiation process, an ion implantation process, or a combination thereof. The polishing resistance patterns 139 and 139B may include a first polishing resistance pattern 139 disposed on an upper surface of the trench key 27 and a second polishing resistance pattern 139B disposed on bottom surfaces of each of the plurality of trenches 127. For example, a thickness of the first polishing resistance pattern 139 may be substantially the same as that of the second polishing resistance pattern 139B. In a CMP process, a material removal rate of each of the polishing resistance patterns 139 and 139B may be different from that of the trench key 27. The material removal rate of each of the polishing resistance patterns 139 and 139B may be lower than that of the trench key 27. In an exemplary embodiment of the present inventive concept, the material removal rate of each of the polishing resistance patterns 139 and 139B may be higher than that of the trench key 27.

Referring to FIGS. 12 and 15, a filling layer 135 may be formed on the trench key 27. For example, the filling layer 135 may fill the plurality of trenches 127 and may cover the trench key 27 and the polishing resistance patterns 139 and 139B. The filling layer 135 may include a material different from that of the trench key 27. In an exemplary embodiment of the present inventive concept, the filling layer 135 may include an oxide such as silicon oxide.

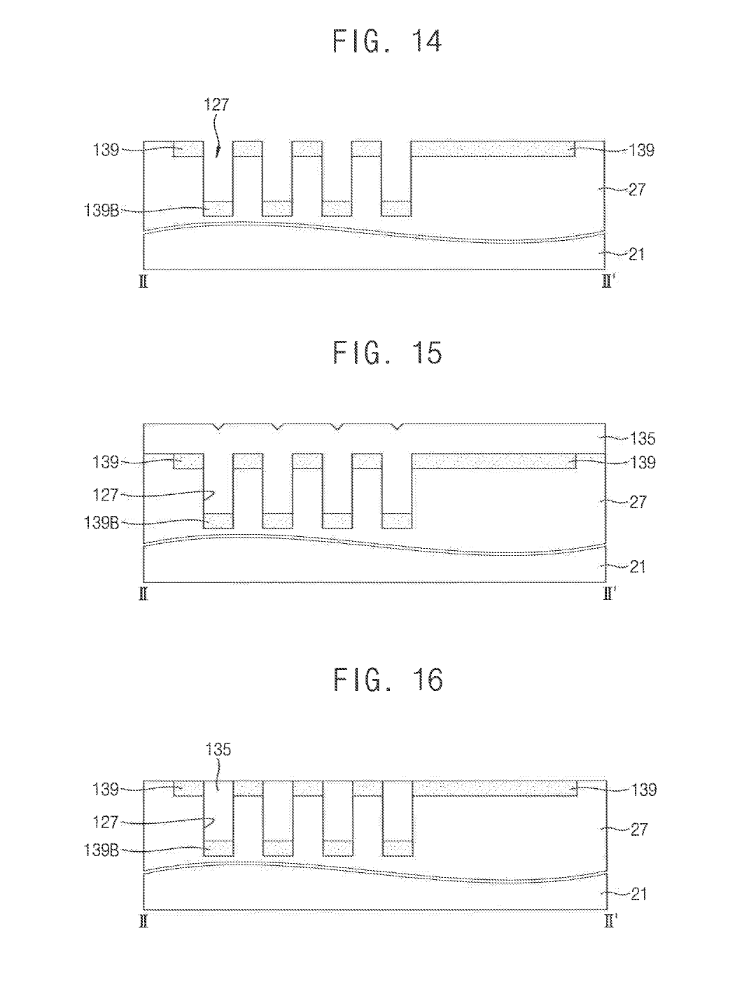

Referring to FIGS. 12 and 16, the filling layer 135 may be partially removed using a CMP process and the first polishing resistance pattern 139 may be exposed. Upper surfaces of the first polishing resistance pattern 139 and the filling layer 135 may be exposed on substantially the same plane. In an exemplary embodiment of the present inventive concept, upper surfaces of the trench key 27, the first polishing resistance pattern 139, and the filling layer 135 may be exposed on substantially the same plane.

In the CMP process, a material removal rate of the filling layer 135 may be different from that of the trench key 27. The material removal rate of the filling layer 135 may be higher than that of the trench key 27. In an exemplary embodiment of the present inventive concept, the material removal rate of each of the polishing resistance patterns 139 and 139B may be higher than that of the trench key 27 and lower than that of the filling layer 135. In an exemplary embodiment of the present inventive concept, the material removal rate of each of the polishing resistance patterns 139 and 139B may be substantially identical to that of the filling layer 135.

In an exemplary embodiment of the present inventive concept, the material removal rate of each of the polishing resistance patterns 139 and 139B may be lower than that of the trench key 27.

In an exemplary embodiment of the present inventive concept, the method of forming the semiconductor device may include planarizing the filling layer 135 using a CMP process until the first polishing resistance pattern 139 is exposed.

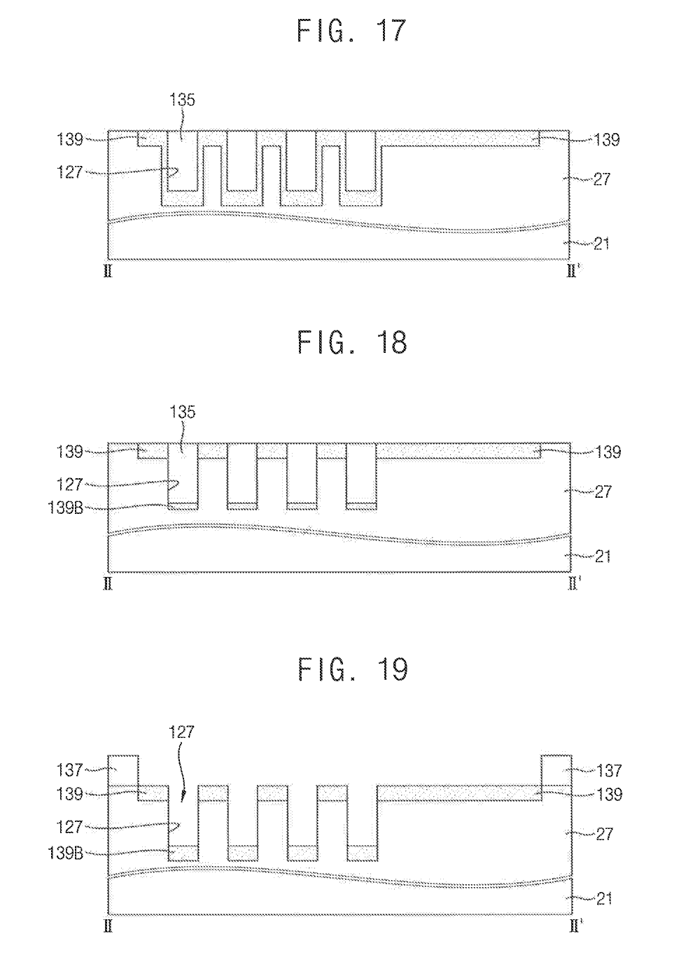

FIGS. 17, 18, 19 and 20 are cross-sectional views illustrating methods of forming a semiconductor device taken along line II-II′ of FIG. 12 according to an exemplary embodiment of the present inventive concept.

Referring to FIGS. 12 and 17, according to an exemplary embodiment of the present inventive concept, a polishing resistance pattern 139 may be formed on an upper surface of the trench key 27 and bottom and side surfaces of each of the plurality of trenches 127. For example, the polishing resistance pattern 139 may be continuous. A filling layer 135 may be planarized using a CMP process so that the polishing resistance pattern 139 and the trench key 27 may be exposed. The filling layer 135 may be formed in the plurality of trenches 127.

Referring to FIGS. 12 and 18, according to an exemplary embodiment of the present inventive concept, polishing resistance patterns 139 and 139B may include a first polishing resistance pattern 139 disposed on an upper surface of the trench key 27 and a second polishing resistance pattern 139B disposed on a bottom surface of each of the plurality of trenches 127. A thickness of the second polishing resistance pattern 139B may be smaller than a thickness of the first polishing resistance pattern 139.

Referring to FIGS. 12 and 19, according to an exemplary embodiment of the present inventive concept, before polishing resistance patterns 139 and 139B are formed, a mask layer 137 may be formed on the trench key 27. The mask layer 137 may partially cover the trench key 27 and may expose the plurality of trenches 127. After the polishing resistance patterns 139 and 139B are formed in the trench key 27 using, for example, a laser irradiation process, an ion implantation process, or a combination thereof, the mask layer 137 may be removed.

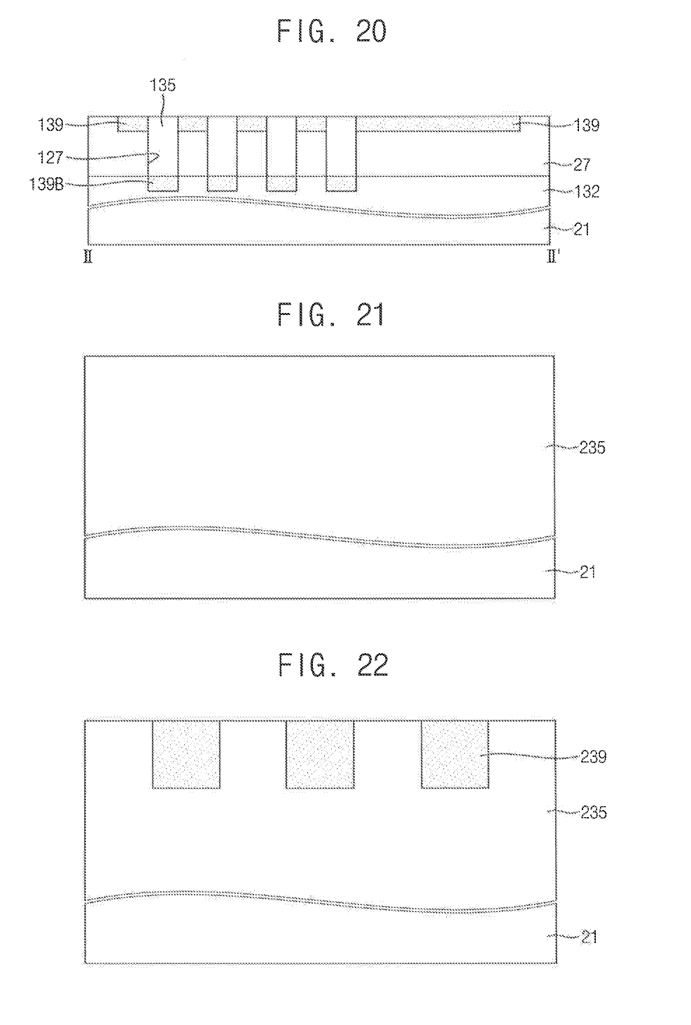

Referring to FIGS. 12 and 20, according to an exemplary embodiment of the present inventive concept, a lower layer 132 may be formed on the substrate 21. The trench key 27 may be formed on the lower layer 132. The trench key 27 may include the plurality of trenches 127. Polishing resistance patterns 139 and 139B may be formed using, for example, a laser irradiation process, an ion implantation process, or a combination thereof. The polishing resistance patterns 139 and 139B may include a first polishing resistance pattern 139, which is disposed on an upper surface of the trench key 27, and a second polishing resistance pattern 13911, which is disposed on a bottom surface of each of the plurality of trenches 127 and formed in the lower layer 132. For example, the lower layer 132 may include trenches in which the second polishing resistance patterns 139B may be disposed. A filling layer 135 may be formed in the plurality of trenches 127. Upper surfaces of the trench key 27, the first polishing resistance pattern 139, and the filling layer 135 may be exposed on substantially the same plane.

FIGS. 21, 22 and 23 are cross-sectional views illustrating a method of forming a semiconductor device according to an exemplary embodiment of the present inventive concept.

Referring to FIG. 21, a thin film 235 may be formed on a substrate 21. The thin film 235 may include an oxide such as silicon oxide, a nitride such as silicon nitride, a semiconductor such as polysilicon, or a combination thereof. In an exemplary embodiment of the present inventive concept, the thin film 235 may include polysilicon.

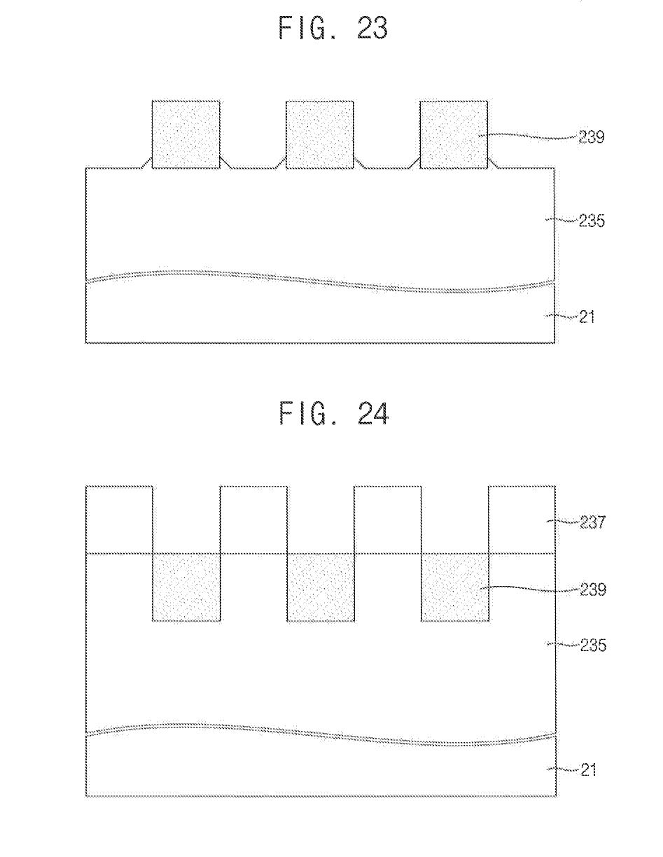

Referring to FIG. 22, a polishing resistance pattern 239 may be formed in the thin film 235 using, for example, a laser irradiation process, an ion implantation process, or a combination thereof.

Referring to FIG. 23, the thin film 235 may be recessed using a CMP process so that the polishing resistance pattern 239 may protrude therefrom. For example, the polishing resistance pattern 239 may be exposed. In the CMP process, a material removal rate of the polishing resistance pattern 239 may be lower than that of the thin film 235. While the CMP process is performed, the thin film 235 may be recessed faster than the polishing resistance pattern 239. An upper surface of the recessed thin film 235 may be formed to be lower than an upper end of the polishing resistance pattern 239. The recessed thin film 235 may partially cover side surfaces of the polishing resistance pattern 239. The further recessed the upper surface of the thin film 235 becomes from an upper surface of the polishing resistance pattern 239, the more the polishing resistance pattern 239 becomes exposed. For example, lower portions of the polishing resistance pattern 239 may be exposed.

In an exemplary embodiment of the present inventive concept, the recessed thin film 235 and the polishing resistance pattern 239 may include polysilicon. The polishing resistance pattern 239 may correspond to a design pattern.

FIG. 24 is a cross-sectional view illustrating a method of forming a semiconductor device according to an exemplary embodiment of the present inventive concept.

Referring to FIG. 24, before a polishing resistance pattern 239 is formed, a mask layer 237 may be formed on a thin film 235. The mask layer 237 may partially expose an upper surface of the thin film 235. The polishing resistance pattern 239 may be formed in the thin film 235 using, for example, a laser irradiation process, an ion implantation process, or a combination thereof. After the polishing resistance pattern 239 is formed, the mask layer 237 may be removed.

According to an exemplary embodiment of the present inventive concept, a method of forming a semiconductor device including forming a polishing resistance pattern and performing a CMP process can be provided. While the CMP process is performed, the polishing resistance pattern can prevent edge collapse of a design pattern. A semiconductor device having a desired pattern can be implemented.

While the present inventive concept has been described with reference to exemplary embodiments thereof, it will be understood by those of ordinary skill in the art that various changes in form and details may be made thereto without departing from the spirit and scope of the present inventive concept.

1. A method of forming a semiconductor device, comprising:
forming a design pattern on a substrate, wherein the design pattern protrudes from the substrate;
forming a filling layer on the substrate, wherein the filling layer at least partially covers the design pattern;
forming a polishing resistance pattern adjacent to the design pattern in the filling layer using a laser irradiation process and/or an ion implantation process; and
removing the filling layer using a chemical mechanical polishing (CMP) process to expose the design pattern.

2. The method of forming the semiconductor device of claim 1, wherein the polishing resistance pattern is closer to an edge of the substrate than is the design pattern.

3. The method of forming the semiconductor device of claim 1, wherein, in the CMP process, the polishing resistance pattern has a material removal rate lower than that of the filling layer.

4. The method of forming the semiconductor device of claim 1, wherein, in the CMP process, a material removal rate of the polishing resistance pattern is substantially identical to that of the design pattern.

5. The method of forming the semiconductor device of claim 1, wherein the polishing resistance pattern comprises:
a first edge; and
a second edge opposite the first edge,
wherein the second edge has a larger slant than the first edge, and
the first edge is disposed between the design pattern and the second edge.

6. The method of forming the semiconductor device of claim 1, wherein, after the CMP process is performed, the filling layer remains between the polishing resistance pattern and the design pattern.

7. The method of forming the semiconductor device of claim 6, wherein upper surfaces of the polishing resistance pattern and the design pattern are exposed on substantially a same plane.

8. The method of forming the semiconductor device of claim 6, wherein, between the polishing resistance pattern and the design pattern, an upper surface of the filling layer is exposed on substantially a same plane as an upper surface of the design pattern.

9. The method of forming the semiconductor device of claim 6, wherein, between the polishing resistance pattern and the design pattern, an upper surface of the filling layer is formed lower than an upper surface of the design pattern.

10. The method of forming the semiconductor device of claim 1, wherein a lowermost end of the polishing resistance pattern is formed lower than an uppermost end of the design pattern.

11. The method of forming the semiconductor device of claim 1, wherein the filling layer comprises an oxide, a nitride, and/or a semiconductor.

12. The method of forming the semiconductor device of claim 1, wherein the ion implantation process comprises implanting carbon (C), and/or nitrogen (N) into the filling layer.

13. The method of forming the semiconductor device of claim 1, further comprising forming a mask layer on the filling layer before the forming of the polishing resistance pattern, wherein the mask layer covers the design pattern and partially exposes the filling layer.

14. A method of forming a semiconductor device, comprising:
forming a design pattern on a substrate, the substrate including a trench;
forming a polishing resistance pattern in the design pattern using a laser irradiation process and/or an ion implantation process;
forming a filling layer on the design pattern, wherein the filling layer fills the trench and covers the design pattern and the polishing resistance pattern; and
removing the filling layer using a chemical mechanical polishing (CMP) process to expose the polishing resistance pattern.

15. The method of forming the semiconductor device of claim 14, wherein the filling layer remains in the trench.

16. The method of forming the semiconductor device of claim 14, wherein upper surfaces of the polishing resistance pattern and the filling layer are exposed on substantially a same plane.

17. The method of forming the semiconductor device of claim 14, wherein, in the CMP process, a material removal rate of the polishing resistance pattern is different from that of the design pattern.

18. The method of forming the semiconductor device of claim 14, wherein, in the CMP process, a material removal rate of the polishing resistance pattern is substantially identical to that of the filling layer.

19. A method of forming a semiconductor device, comprising:
forming a protruding design pattern on a substrate;
forming a filling layer on the substrate, wherein the filling layer covers side surfaces and an upper surface of the design pattern;
forming a polishing resistance pattern adjacent to the design pattern and in the filling layer using a laser irradiation process; and
planarizing the filling layer and the polishing resistance pattern using a chemical mechanical polishing (CMP) process until the design pattern is exposed,
wherein the polishing resistance pattern is disposed between an edge of the substrate and the design pattern, and
wherein in the CMP process, a material removal rate of the polishing resistance pattern is different from that of the filling layer.

20. The method of forming the semiconductor device of claim 19, wherein the polishing resistance pattern comprises:
a first edge; and
a second edge opposite the first edge,
wherein, after the CMP process is performed, the second edge is slanted and the first edge straight, and
the second edge is closer to the edge of the substrate than is the first edge.

21-23. (canceled)
